(19) United States
(12) Patent Application Publication
(10) Pub. No.: US 2008/0030382 A1
(43) Pub. Date: Feb. 7, 2008

(54) Real Number Coding Apparatus

(76) Inventor: Shu-Kai Yang, Jhonghe City (TW)

Correspondence Address: LAW OFFICES OF LAI AND ASSOCIATES, P.C., 5800 RANCHESTER STE 200, HOUSTON, TX, 77036, US

(21) Appl. No.: 11/457,963

(22) Filed: Jul. 17, 2006

(51) Int. Cl. H03M 7/38

(52) U.S. Cl. 341/51

(57) ABSTRACT

A real number coding apparatus is disclosed. The apparatus receives a plurality of real numbers that is composed of a plurality of bits. The apparatus selects a bit corresponding to a certain condition, such as the bits at the same position. The plurality of bits is then coded to generate a coding output data. In addition, the apparatus can configure the real numbers to be an array. Every real numbers are formed a row of the array. Next, bits of the column of the array are coded to generate coding output data.

### FIELD OF THE INVENTION

The present invention relates to a real number coding apparatus, and more particularly to the real number coding apparatus that uses bits between different real numbers.

### BACKGROUND OF THE INVENTION

Currently, computers are in widespread use in our daily life, especially for communication, data processing or entertainments. In information generation, complex data are needed to be stored and transmitted. Although bandwidths for transmitting media are continuously increased, it may not deal with increased data quantity. To reduce the loadings of communication channels, a coding technique for numbers is developed. Under a condition of keeping original data of messages, the storage space required for data is reduced. In a conventional encoding/decoding application, integers are dealt with by the application. If real numbers need to be dealt with by encoding/decoding, floating numbers are particularly encoded/decoded after the floating numbers are approximated to integers. Hence, the accuracy is decreased. While performing three-dimensional coordinate operations, data loss caused by encoding/decoding floating numbers may influence three-dimensional effects. There is still no efficient and simple system to encode/decode real numbers and to preserve the accuracy. Therefore, a real number coding/decoding system with high coding efficiency is provided that does not slow down the loading of the communication channels, but also achieves the goal of real-time communication.

To overcome the foregoing issues, the inventor of the present invention based on years of experience on related research and development of the data coding technique invents a real number coding apparatus to overcome the foregoing shortcoming.

### SUMMARY OF THE INVENTION

In view of the foregoing issues, an objective of the present invention is to provide a real number coding apparatus to improve coding efficiency of real numbers and to prevent the data loss.

In accordance with the objective of the present invention, a real number coding apparatus includes a receiving unit, a selection unit and a first coding unit. The receiving unit is for receiving a plurality of real numbers. Every real numbers are composed of a plurality of bits. The selection unit selects a bit corresponding to a specific condition from every real numbers. The first coding unit performs a first coding action for a plurality of bits which has been selected to generate a first coding output data.

In addition, the real number coding apparatus of the present invention further includes a logical arithmetic unit for performing a logical operation for the plurality of bits or the bits of a column of the array before performing the first coding action.

Moreover, the real number coding apparatus of the present invention further includes a second coding unit for performing a second coding action for a plurality of numbers composed of a plurality of bits from every real numbers to generate a second coding output data.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 is a flowchart of operating a real number coding apparatus according to an embodiment of the present invention;

FIG. 2 is a schematic diagram of a real number array according to an embodiment of the present invention;

FIG. 3 is a schematic diagram of a real number array after performing a vertical an exclusive OR (XOR) according to FIG. 2;

FIG. 4 is a flowchart of operating a real number coding apparatus according to another embodiment of the present invention;

FIG. 5A and FIG. 5B are schematic diagrams of real number arrays according to embodiments of the present invention;

FIG. 6 is a block diagram of a real number coding apparatus according to an embodiment of the present invention; and

FIG. 7 is a block diagram of a real number coding apparatus according to another embodiment of the present invention.

### DETAILED DESCRIPTION OF THE PREFERRED EMBODIMENTS

Refer to the related figures for a real number coding apparatus according to a preferred embodiment of the present invention, wherein the same elements are described by the same reference numerals.

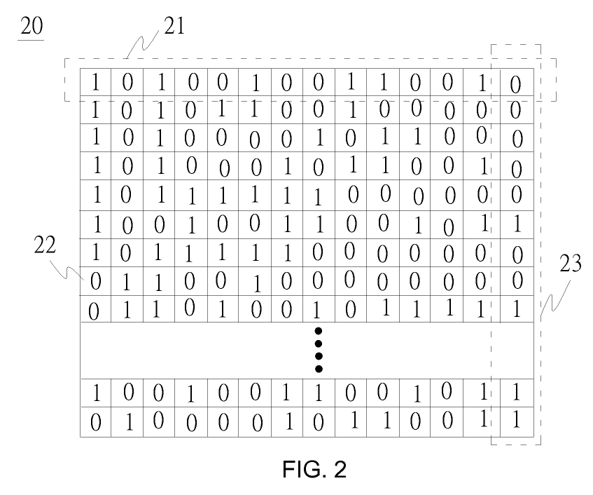

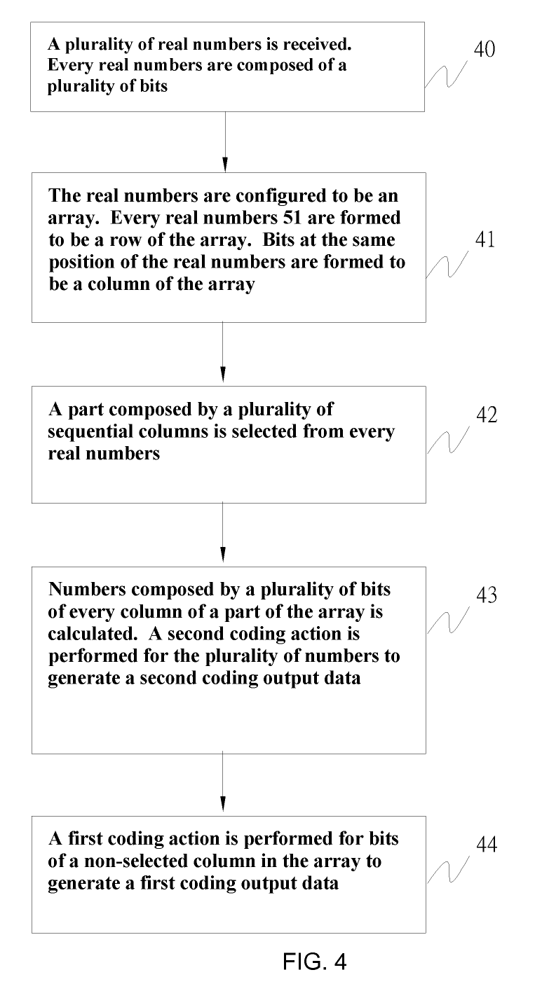

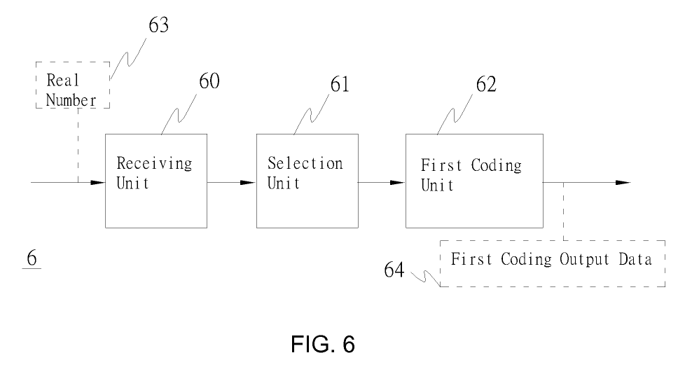

Referring to FIG. 6, a block diagram illustrates a real number coding apparatus according to an embodiment of the present invention. The real number coding apparatus 6 includes a receiving unit 60, a selection unit 61 and a first coding unit 62. The receiving unit 60 is for receiving a plurality of real numbers 63. Every real numbers 63 is composed of a plurality of bits (as shown in FIG. 2). The selection unit 61 selects a bit corresponding to the specific condition from every real numbers 63. The first coding unit 62 is for performing a first coding action for a plurality of bits to generate a first coding output data 64. The bit corresponding to the specific condition is a bit at the same position of every real numbers. In addition, the selection unit 61 also configures the real numbers to be an array. Every real numbers are formed a row (e.g. the real numbers 21 as shown in FIG. 4). Bits at the same position of the real numbers are formed a column of the array. The first coding action is also performed for the bits of the column of the array to generate the first coding output data. Moreover, the selection unit 61 can divide the real numbers into many parts to perform decoding based on a received real number data format.

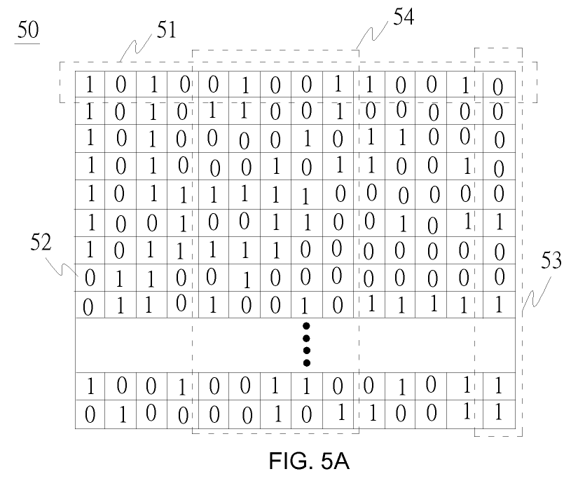

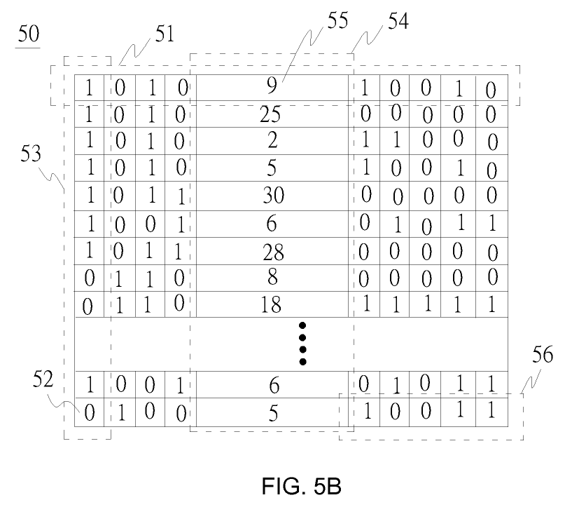

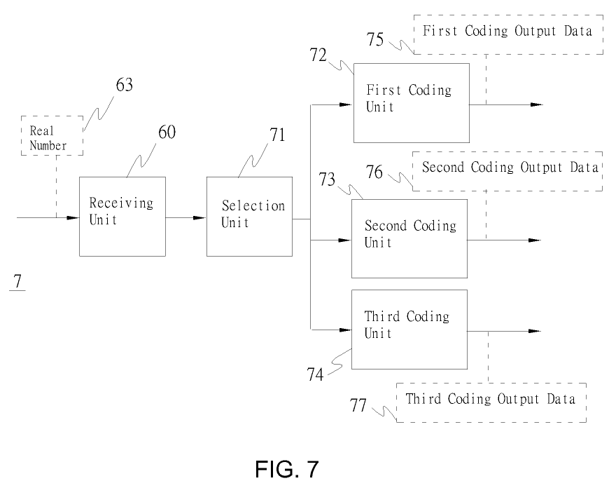

Referring to FIG. 7, a block diagram illustrates a real number coding apparatus according to an embodiment of the present invention. The real number coding apparatus 7 includes a receiving unit 60, a selection unit 71, a first coding unit 72, a second coding unit 73 and a third coding unit 74. The receiving unit 60 receives a plurality of real numbers 63 formed by bits. The selection unit 71 configures the real numbers 63 to be an array. Every real numbers are formed a row of the array, as the array 50 shown in FIG. 5B. The selection unit 71 then transmits a first column, a second column, a third column, and a fourth column of the array (the left columns of the array 50) to the first coding unit 72. The first coding unit performs a first coding action to generate a first coding output data 75 based on the vertical relationship of bits of every column. The selection unit 71 then calculates numbers 55 formed by bits at the same row of the array. The plurality of numbers 55 is then transmitted to the second coding unit 73 for performing a second coding action to generate a second coding output data 76. The selection unit 71 transmits bits 66 of every row which are not selected to the third coding unit 74 for performing a third coding action to generate a third coding output data 77.

For example, if received data is floating point data, a sign bit s, an exponent e and a mantissa m are included. According to these data characteristics, the s can be transmitted to the first coding unit 72, the e can be transmitted to the second coding unit 73, and the m can be transmitted to the third coding unit 74 to perform coding.

The first coding action, the second coding action and the third coding action are preferably a run length coding, a difference coding or a predicative coding. The use of these coding methods is well-known to those of ordinary skilled in the art that is therefore not illustrated herein.

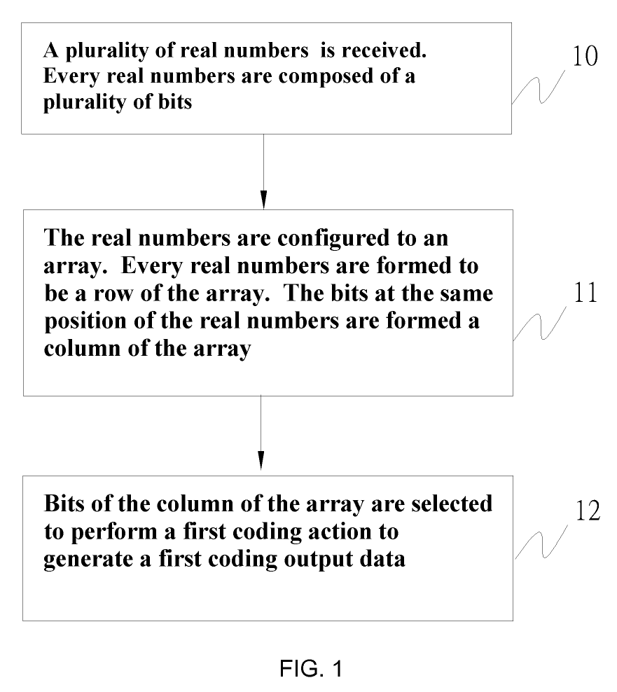

Referring to FIG. 1 and FIG. 2, FIG. 1 is flowchart illustrating an operating procedure in a real number coding apparatus according to an embodiment of the present invention and FIG. 2 is a schematic diagram illustrating an array according to FIG. 1. In FIG. 1, the operating procedure includes the following steps:

Step 10: a plurality of real numbers 21 is received. Every real numbers 21 are composed of a plurality of bits 22.

Step 11: the real numbers 21 are configured to an array 20. Every real numbers 21 are formed to be a row of the array. The bits at the same position of the real numbers are formed a column 23 of the array.

Step 12: bits of the column 23 of the array 20 are selected to perform a first coding action to generate a first coding output data.

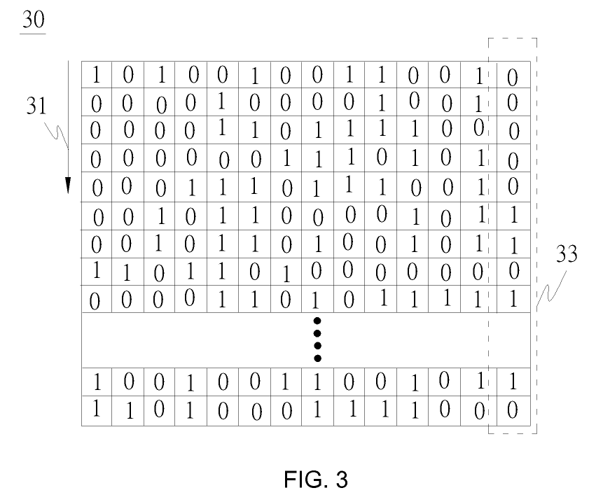

In addition, the operating procedure based on demands can perform a logical operation for the bits of the column of the array before performing the first coding action. The logical operation is preferably an exclusive OR (XOR). As shown in FIG. 3, the array 20 uses a downward direction 31 to perform an XOR for bits of every column of the array 20. The first coding action is performed for bits of a column 33 of an array 30 to generate a first coding output data. It should be noted that the aforementioned embodiments take the array to be examples, it is to be understood that the embodiments are not limited thereto. Any bit corresponding to a specific condition is selected from every real numbers and a first coding action is performed for the plurality of bits to generate the apparatus of the first coding output data, which are encompassed the scope of the invention.

Referring to FIG. 4, FIG. 5A and FIG. 5B, a flowchart illustrates an operating procedure for a real number coding apparatus according to another embodiment of the present invention and schematic diagrams illustrate corresponding real numbers according to an embodiment of the present invention. In FIG. 4, the operating procedure includes the following steps:

Step 40: a plurality of real numbers 51 is received. Every real numbers 51 are composed of a plurality of bits 52.

Step 41: the real numbers 51 are configured to be an array 50. Every real numbers 51 are formed to be a row of the array. Bits at the same position of the real numbers 51 are formed to be a column 53 of the array.

Step 42: a part 54 (as shown in FIG. 5A) composed by a plurality of sequential columns is selected from every real numbers 51.

Step 43: numbers 55 (as shown in FIG. 5B) composed by a plurality of bits of every column of a part 54 of the array is calculated. A second coding action is performed for the plurality of numbers 55 to generate a second coding output data.

Step 44: a first coding action is performed for bits of a non-selected column 53 in the array 50 to generate a first coding output data.

In addition, the operating procedure further includes performing a subtraction operation for the plurality of numbers 55 before performing the second coding action in order to reduce coding data amounts. Moreover, the operating procedure further includes performing a third coding action for non-selected bits of every real numbers to increase operating flexibility for different data formats. The array 50 as shown in FIG. 5B, the first column to the fourth column of the array 50 (at the left side of the array 50) uses bits at the same column to perform the first coding action in order to generate a first coding output data. A fifth column to a ninth column (a part 54 of the array) is to calculate numbers 55 composed of bits first. A second coding action is performed for the plurality of numbers 55 to generate a second coding output data. Next, a third coding action is performed for non-selected bits 56 of every row to generate a third coding output data.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A real number coding apparatus, comprising:
a receiving unit received a plurality of real numbers, every said real numbers being composed of a plurality of bits;
a selection unit selected a bit corresponding to the specific condition from every said real numbers; and
a first coding unit performed a first coding action for said plurality of bits to generate a first coding output data.

2. The real number coding apparatus of claim 1, wherein said bit corresponding to the specific condition is a bit at the same position of every said real numbers.

3. The real number coding apparatus of claim 1, wherein said selection unit configures said real numbers to be an array first, and every said real numbers form a row, and bits at the same position of said real numbers form a column of said array, and said first coding action is performed for said bits of said column of said array to generate said first coding output data.

4. The real number coding apparatus of claim 1, wherein said real number coding apparatus further comprises a logical arithmetic unit for performing a logic operation for said plurality of bits or said bits of said column of said array before performing said first coding action.

5. The real number coding apparatus of claim 4, wherein said logic operation is an exclusive OR (XOR).

6. The real number coding apparatus of claim 1 or 3, wherein said real number coding apparatus further comprises a second coding unit for performing a second coding action for numbers formed by a plurality of bits in every said real numbers.

7. The real number coding apparatus of claim 6, wherein said second coding unit performs a subtraction operation for said plurality of numerals before performing said second coding action.

8. The real number coding apparatus of claim 1 or 3, wherein said first coding action uses a length coding, a differential coding or a prediction coding.

9. The real number coding apparatus of claim 6, wherein said second coding action uses a run length coding, a difference coding or a predictive coding.

10. The real number coding apparatus of claim 1, 3 or 6, wherein said real number coding apparatus further comprises a third coding unit for performing a third coding action for non-selected bits in every real numbers.

11. The real number coding apparatus of claim 10, wherein said third coding action uses a run length coding, a difference coding or a predictive coding.
